(19) United States
(12) Patent Application Publication
(10) Pub. No.: US 2006/0068611 A1
(43) Pub. Date: Mar. 30, 2006

(54) Heat transfer device and system and method incorporating same

(76) Inventors: Stanton Earl Weaver JR., Northville, NY (US); James William Bray, Niskayuna, NY (US); Ahmed Elasser, Latham, NY (US); Seth Thomas Taylor, Niskayuna, NY (US)

Correspondence Address: Patrick S. Yoder;FLETCHER YODER, P.O. Box 692289, Houston, TX, 77269-2289, US

(21) Appl. No.: 10/955,639

(22) Filed: Sep. 30, 2004

(51) Int. Cl. H05K 1/00; C23C 14/00; B32B 37/00; H01S 4/00

(52) U.S. Cl. 439/65; 204/192.12; 29/592.1; 156/272.2

(57) ABSTRACT

A method of manufacturing a heat transfer device including providing first and second thermally conductive substrates that are substantially atomically flat, providing a patterned electrical barrier on the first or second thermally conductive substrates and disposing a low work function material on the first or second thermally conductive substrates in an area oriented between the patterned electrical barrier in a configuration in which the first and second thermally conductive substrates are positioned opposite from one another. The method also includes bonding the first and second thermally conductive substrates in the configuration and extracting a plurality of units having opposite sections of the first and second thermally conductive substrates, each unit having a portion of the patterned electrical barrier disposed about the low work function material.

### BACKGROUND

The invention relates generally to heat transfer devices, and particularly, to solid state heat transfer devices.

Heat transfer devices may be used for a variety of heating/cooling and power generation/heat recovery systems, such as refrigeration, air conditioning, electronics cooling, industrial temperature control, waste heat recovery, and power generation. These heat transfer devices are also scalable to meet the thermal management needs of a particular system and environment. Unfortunately, existing heat transfer devices, such as those relying on refrigeration cycles, are relatively inefficient and environmentally unfriendly due to mechanical components such as compressors and the use of refrigerants.

In contrast, solid-state heat transfer devices offer certain advantages, such as the potential for higher efficiencies, reduced size and weight, reduced noise, and being more environmentally friendly. For example, thermotunneling devices transfer heat by tunneling hot electrons from one electrode to another electrode across a nanometer-scale barrier. The heat transfer efficiency of these thermotunneling devices depends upon various factors, such as material characteristics (for electrodes and barrier), electrode alignment, electrode spacing, and thermal losses. For efficient operation of these thermotunneling devices, the electrodes should have a low work function, the barrier should ideally be in vacuum, and the spacing between the electrodes should be on the order of 4-20 nanometers. Unfortunately, electrode spacing is particularly difficult to achieve and maintain in these thermotunneling devices. Thus, achieving efficient thermotunneling devices can be problematic.

Accordingly, a need exists for creating a heat transfer device with low work function electrodes and a controlled spacing between the electrodes.

### BRIEF DESCRIPTION

In accordance with certain embodiments, a method of manufacturing a heat transfer device includes providing first and second thermally conductive substrates that are substantially atomically flat, providing a patterned electrical barrier on the first or second thermally conductive substrates and disposing a low work function material on the first or second thermally conductive substrates in an area oriented between the patterned electrical barrier in a configuration in which the first and second thermally conductive substrates are positioned opposite from one another. The method also includes bonding the first and second thermally conductive substrates in the configuration and extracting a plurality of units having opposite sections of the first and second thermally conductive substrates, each unit having a portion of the patterned electrical barrier disposed about the low work function material.

In accordance with certain embodiments, the present technique has a heat transfer device including first and second thermally conductive substrates that are positioned opposite from one another, wherein the first and second thermally conductive substrates are each substantially atomically flat and a patterned electrical barrier is disposed between the first and second thermally conductive substrates on the first or second thermally conductive substrates. The heat transfer device also includes a low work function material disposed between the first and second thermally conductive substrates on the first or second thermally conductive substrates in an area oriented between the patterned electrical barrier, wherein introduction of a current flow between the first and second thermally conductive substrates enables heat transfer between the first and second thermally conductive substrates via a flow of electrons between the first and second thermally conductive substrates.

In accordance with certain embodiments, the present technique has a method of operation of a heat transfer device including passing hot electrons across a thermotunneling gap between first and second thermally conductive substrates, wherein the thermotunneling gap is formed by a patterned electrical barrier disposed about a low work function material on one of the first or second thermally conductive substrates.

### DRAWINGS

These and other features, aspects, and advantages of the present invention will become better understood when the following detailed description is read with reference to the accompanying drawings in which like characters represent like parts throughout the drawings, wherein:

FIG. 1 is a diagrammatical illustration of a system having a heat transfer device in accordance with embodiments of the present technique;

FIG. 2 is a diagrammatical illustration of a cooling system having a heat transfer device in accordance with embodiments of the present technique;

FIG. 3 is a diagrammatical illustration of a heating system having a heat transfer device in accordance with embodiments of the present technique;

FIG. 4 is a flow chart illustrating a method of manufacturing a heat transfer device in accordance with an embodiment of the present technique;

FIG. 5 is a flow chart illustrating a method of manufacturing a heat transfer device in accordance with another embodiment of the present technique;

FIG. 6 is a flow chart illustrating a method of manufacturing a heat transfer system having a plurality of heat transfer units in accordance with embodiments of the present technique;

FIG. 7 is a diagrammatical illustration of a substrate having a patterned electrical barrier for use in a heat transfer device in accordance with embodiments of the present technique;

FIG. 8 is a diagrammatical illustration of a substrate having a patterned electrical barrier and a low work function material for use in a heat transfer device in accordance with embodiments of the present technique;

FIG. 9 is a diagrammatical illustration of a heat transfer unit extracted from the patterned substrate of FIG. 8 in accordance with embodiments of the present technique;

FIG. 10 is a diagrammatical illustration of an assembled block of a heat transfer device having a thermotunneling gap in accordance with embodiments of the present technique;

FIG. 11 is a diagrammatical illustration of an assembled module of a heat transfer device having a plurality of extracted blocks from the patterned substrate of FIG. 8 in accordance with embodiments of the present technique;

FIG. 12 is a diagrammatical illustration of a module having an array of heat transfer devices in accordance with embodiments of the present technique;

FIG. 13 is a diagrammatical illustration of an extracted block from the patterned substrate of FIG. 8 with an additional coating in accordance with embodiments of the present technique; and

FIG. 14 is a diagrammatical illustration of an assembled block of a heat transfer device having additional wafers in accordance with embodiments of the present technique.

### DETAILED DESCRIPTION

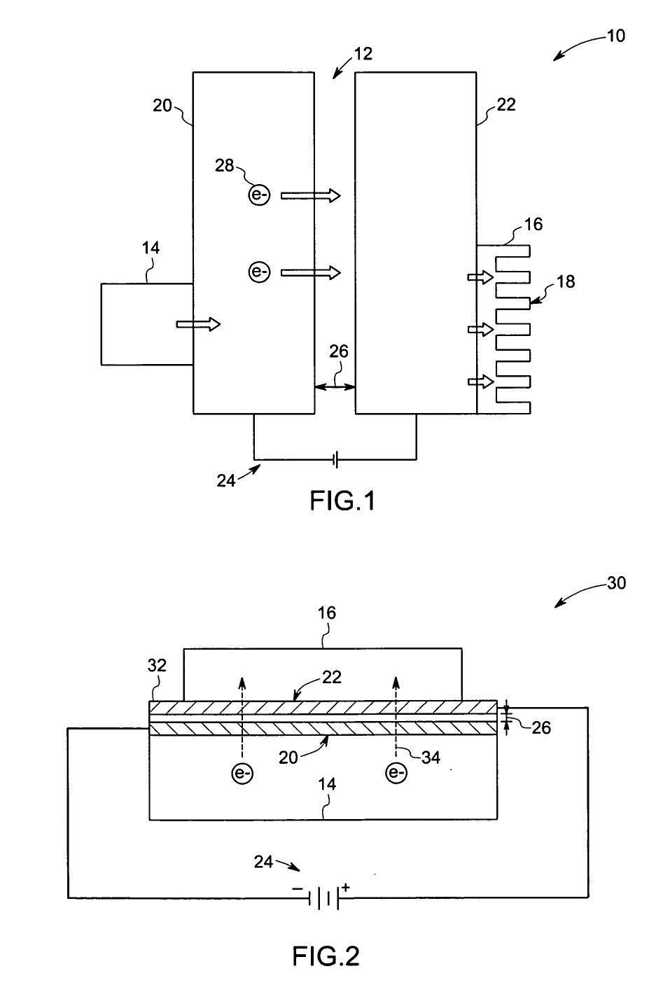

Referring now to the drawings, FIG. 1 illustrates a system 10 having a thermotunneling-based heat transfer device in accordance with certain embodiments of the present technique. As illustrated, the system 10 includes a thermotunneling device 12 that transfers heat from an area or object 14 to another area or object, such as a heat sink 16, which heat sink 16 then dissipates the heat via fins 18. More specifically, the thermotunneling device 12 comprises a first electrode 20 thermally coupled to the object 14 and a second electrode 22 that is thermally coupled to the heat sink 16. Further, an input voltage source 24 is coupled to the first electrode 20 and the second electrode 22 that are separated by a thermotunneling gap 26. In operation, the input voltage source 24 provides a flow of current through the first and second electrodes 20 and 22, thereby creating a tunneling flow of hot electrons 28 between the electrodes 20 and 22 across the thermotunneling gap 26. In this embodiment, the flow of current via the input voltage source 24 enables hot electrons 28 to leave their orbit and tunnel across the thermotunneling gap 26, thus transporting heat. As a result of this tunneling flow of hot electrons 28, the thermotunneling device 12 facilitates heat transfer away from the object 14 towards the heat sink 16. At the heat sink 16, the fins 18 facilitate heat transfer away from the system 10.

In this embodiment, the thermotunneling gap 26 is formed by vacuum that provides a minimum thermal back path to enhance the efficiency of the thermotunneling device 12. In certain embodiments, the thermotunneling gap 26 has a spacing ranging between approximately 4 nanometers to about 20 nanometers. The nanometer gap between the first and second electrodes 20 and 22 facilitates a substantial reduction in the tunneling of cold electrons across the thermotunneling gap and facilitates a substantial increase the tunneling of hot electrons across the thermotunneling gap 26. Further, the nanometer gap between the first and second electrodes 20 and 22 advantageously reduces a high voltage requirement across the first and second electrodes 20 and 22 for facilitating the tunneling of electrons. Thus, a nanometer gap between the first and second electrodes 20 and 22 enables the tunneling of electrons at a relatively lower voltage, thereby enhancing the efficiency of the thermotunneling device 12.

The nanometer spacing and a bias voltage across the thermotunneling gap 26 ensure that the heat flow is substantially unidirectional. In the illustrated embodiment, the heat flow is unidirectional from the object 14 towards the heat sink 16, thus making the object 14 cooler by transferring the heat to the heat sink 14. In certain embodiments, the thermotunneling device 12 may facilitate the heating or cooling of a closed environment. It should be noted that the thermotunneling device 12 may be operable at or near room temperature. In certain embodiments, the first and second electrodes 20 and 22 comprise dissimilar materials that enhance the tunneling of electrons because of a peltier effect, thereby, enhancing the efficiency of the thermotunneling device 12. However, the direction of current flow may be selected based upon a desired direction of the thermotunneling of electrons between the first and second electrodes 20 and 22.

FIG. 2 illustrates a cooling system 30 having a heat transfer device, such as a thermotunneling device 32, in accordance with embodiments of the present technique. The thermotunneling device 32 comprises the first electrode 20 and the second electrode 22 separated by the thermotunneling gap 26. As illustrated, the first electrode 20 is thermally coupled to the object/area 14 and the second electrode 22 is thermally coupled to the object/area 16. Further, the first electrode 20 and the second electrode 22 are coupled to the input voltage source 24 with the polarity as shown in FIG. 2. In operation, the input voltage source 24 activates the thermotunneling device 32 at a pre-determined tunneling current. As the current flows from the first electrode 20 to the second electrode 22, the thermotunneling device 32 forces electrons to move from the object 14 toward the object 16 in a direction 34 over the thermotunneling gap 26. The movement of electrons in the direction 34 transfers heat away from the object 14, across the gap 26, and into the object 16, wherein the heat is further transferred away from the system 30. Advantageously, this thermotunnelling-based heat transfer cools the object 14.

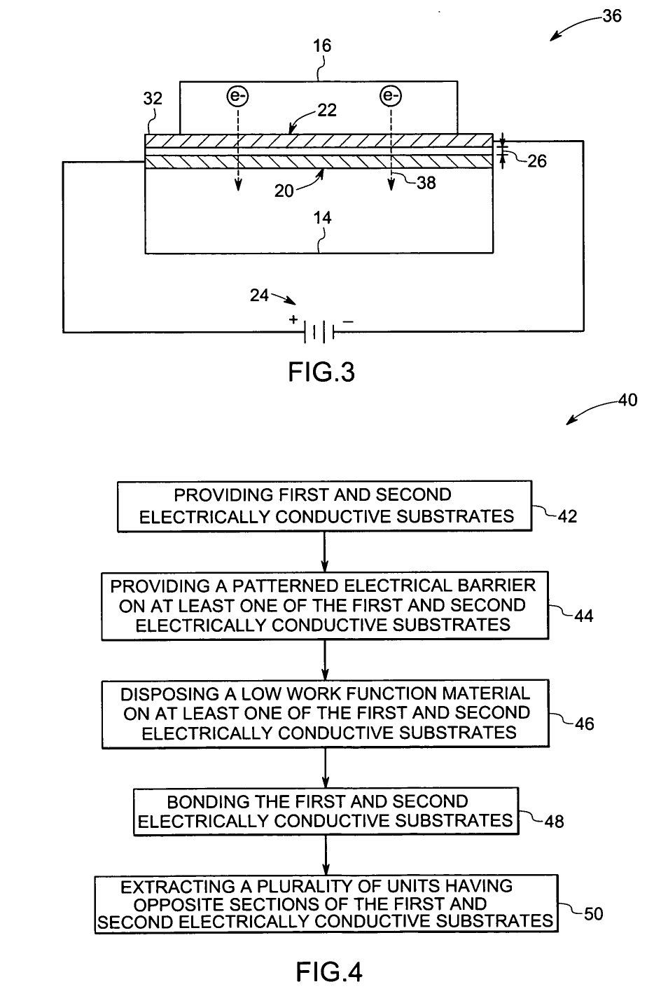

FIG. 3 illustrates a heating system 36 having the thermotunneling device 32 in accordance with embodiments of the present technique. As described above, the thermotunneling device 32 includes the two electrodes 20 and 22 that are thermally coupled to the objects 14 and 16, respectively. In addition, the thermotunneling device 32 is coupled to the input voltage source 24. As illustrated, the polarity of the input voltage source 24 in the heating system 36 is reversed as compared to the cooling system 30 as shown in FIG. 2. This enables the electrons to flow from the object 16 to the object 14 in a direction 38, thus heating the object 14 by transferring heat from the object 16 to the object 14. As described above, the thermotunneling device 32 may be employed for heating or cooling of objects 14 and 16. In certain embodiments, the thermotunneling device 32 may be employed for power generation by maintaining a temperature gradient between the first and second objects 14 and 16, respectively. The thermotunneling device 32 as described above may be fabricated by a variety of techniques, such as the exemplary techniques described in detail below with reference to FIGS. 4, 5 and 6.

Referring first to FIG. 4, a flow chart illustrates an exemplary process 40 for manufacturing the thermotunneling device 32 of FIGS. 1, 2 and 3 in accordance with embodiments of the present technique. The process 40 begins by providing first and second thermally conductive substrates (block 42). In this embodiment, the first and second thermally conductive substrates comprise substantially atomically flat materials having a low emissivity. In certain embodiments, the emissivity of the first and second thermally conductive substrates is less than about 0.05. For example, highly doped n-type silicon wafers may be used for the first and second thermally conductive substrates. Alternatively, highly doped p-type silicon wafers may be used for the first and second thermally conductive substrates. In certain embodiments, the first and second thermally conductive substrates comprise an electrically insulating substrate having an electrically conductive coating disposed on the electrically insulating substrate. In some other embodiments, highly polished thermally and electrically conductive metals may be employed for the first and second thermally conductive substrates. Examples of such metals include aluminum, copper, nickel, and alloys thereof.

At block 44, a patterned electrical barrier layer (e.g., a plurality of frames or borders) is provided on at least one of the first and second thermally conductive substrates. The patterned electrical barrier layer provides perimeter support to open areas on the first and second thermally conductive substrates and facilitates control of alignment of the first and second thermally conductive substrates during subsequent bonding of the first and second thermally conductive substrates. The bonding of the first and second thermally conductive substrates will be described in detail below. The thickness of the patterned electrical barrier layer is adjusted to a pre-determined value based upon the work function of the first and second thermally conductive substrates and a desired thermotunneling gap. It should be noted that, as used herein, the term “work function” is defined by the least amount of energy required to remove an electron from the surface of a solid material, to a point outside the solid material. In certain embodiments, the thickness of the patterned electrical barrier layer is in a range from about 4 nanometers to about 20 nanometers. Further, the thickness of the patterned electrical barrier layer provides the desired thermotunneling gap for facilitating the tunneling of electrons between the first and second thermally conductive substrates. In certain embodiments, where the work function of the first and second thermally conductive substrates is substantially low, the thickness of the patterned electrical barrier layer may be greater than 10 nanometers.

Moreover, embodiments of the patterned electrical barrier layer are grown on at least one of the first and second thermally conductive substrates. The patterned electrical barrier may be grown or deposited on at least one of the first and second thermally conductive substrates by techniques such as thermal oxidation, chemical vapor deposition, enhanced plasma assisted chemical vapor deposition, sputtering, evaporation and spin coating. In certain embodiments, the patterned electrical barrier layer comprises a material having a low thermal conductivity. Examples of such materials include oxides, polymers, nitrides, and silica-based aerogels.

Next, a low work function material is disposed on at least one of the first and second thermally conductive substrates to form first and second electrodes (block 46). In certain embodiments, the low work function material is disposed on the first and second thermally conductive substrates in an area disposed between the patterned electrical barrier layer. In other words, the patterned electrical barrier layer is disposed about the low work function material on the same one of the first or second thermally conductive substrates. Alternatively, the low work function material may be disposed on either first or second thermally conductive substrates in an area aligned with the area between the patterned electrical barrier layer on either first or second thermally conductive substrates. For example, one embodiment has the patterned electrical barrier layer disposed on the first thermally conductive substrate, while the low work function material is disposed on the second thermally conductive substrate in an area opposite from and within the borders of the patterned electrical barrier layer.

The low work function material may be deposited on the first and second thermally conductive substrates by metal deposition techniques, such as ion implantation, evaporation, sputtering, vapor deposition, plasma enhanced chemical vapor deposition, chemical vapor deposition, pulsed laser deposition and so forth. In various embodiments, the low work function material may comprise an alkalide, an electride, a rare-earth sulfide, an oxide of barium, strontium, calcium and their combinations thereof. In certain embodiments, the low work function material comprises a multilayer thin film structure. In this embodiment, the multilayer thin film structure comprises at least one metal layer disposed adjacent to at least one wide band-gap semiconductor layer. In addition, the low work function material may be deposited on the entire substrate either below or above the patterned electrical barrier. In certain embodiments, a low emmissivity material may be disposed on the low work function material to minimize the radiation parasitic thereby enhancing the efficiency of the thermotunneling device.

Moreover, the process 40 includes bonding the first and second thermally conductive substrates in a wafer bonder (block 48). In certain embodiments, the first and second thermally conductive substrates are placed inside a vacuum chamber and are bonded at a desired temperature, thus forming a vacuum within the tunneling gap to enhance the efficiency of the heat transfer device. Alternatively, the bonding of the first and second thermally conductive substrates may be performed in an inert gas environment, thus filling the tunneling gap with an inert gas such as xenon. In some embodiments, a thermal anneal of the first and second thermally conductive substrates may be performed at a desired temperature to improve the bond between the first and second thermally conductive substrates. Embodiments of this bonding step 48 comprise positioning the first and second thermally conductive substrates, such that at least one portion (e.g., frame or border) of the patterned electrical barrier and at least one portion (e.g., square or block) of the low work function material on the first and second thermally conductive substrates are substantially opposite each other.

Further, at block 50, a plurality of units having opposite sections of the bonded first and second thermally conductive substrates are extracted to form a plurality of heat transfer devices. Each of these extracted units has a portion of the patterned electrical barrier disposed about the low work function material between the bonded first and second thermally conductive substrates. The extracted units also may be coupled electrically and assembled as a heat transfer module to provide a desired heating or cooling capacity based on certain thermal management needs.

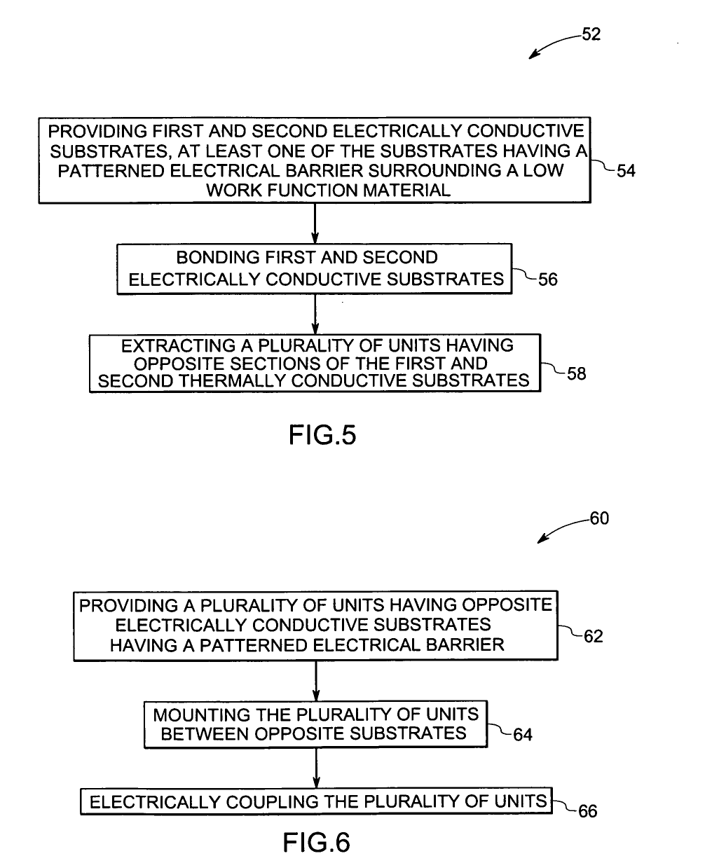

Turning now to FIG. 5, a flow chart illustrates an alternate exemplary process 52 of manufacturing the heat transfer devices of FIGS. 1, 2 and 3 in accordance with embodiments of the present technique. The process 52 begins by providing first and second thermally conductive substrates (block 54). Again, embodiments of the first and second thermally conductive substrates are substantially atomically flat. Further, at least one of the first and second thermally conductive substrates has a patterned electrical barrier (e.g., a plurality of frames or borders) surrounding a low work function material (e.g., a square or block) in at least one area disposed/aligned between the patterned electrical barrier. The first and second thermally conductive substrate layers may be pre-fabricated by techniques as illustrated above with reference to FIG. 4.

Next, at block, 56 the first and second thermally conductive substrates are bonded together. In certain embodiments, the bonding step 54 may be performed in vacuum at a desired temperature, thus forming a vacuum within a tunneling gap between the first and second thermally conductive substrates to enhance the efficiency of the heat transfer device. Moreover, the first and second thermally conductive substrates may be positioned to align the low work function material surrounded by the patterned electrical barrier (e.g., a frame or border) with the low work function material disposed on the opposite one of the first and second thermally conductive substrates. Subsequently, at block 58, the process 52 continues by extracting a plurality of units from the bonded first and second thermally conductive substrates, wherein each of the units has a portion of the patterned electrical barrier (e.g., frame or border) surrounding a portion of the low work function material (e.g., a square or block). As mentioned above, these extracted units may be used individually or collectively for use as a heat transfer device for a system, such as a refrigeration system, an electronics cooling system, and so forth.

Referring now to FIG. 6, a flow chart illustrates an exemplary process 60 for manufacturing a heat transfer system in accordance with embodiments of the present technique. The process 60 begins by providing a plurality of units having opposite thermally conductive substrates (block 62). In this embodiment, each of the plurality of units comprises a patterned electrical barrier layer disposed about a low work function material to form a thermotunneling gap. In operation, each of the plurality of units facilitates thermotunneling of electrons between the opposite thermally conductive substrates. The thermally conductive substrates with the patterned electrical barrier layers disposed about the low work function material form electrodes for the transfer of electrons across the thermotunneling gap. Moreover, the plurality of units may be fabricated as explained above with reference to FIG. 4 and FIG. 5. Next, at block 64, the plurality of units having the patterned electrical barrier layer is mounted between opposite substrates. Finally, the units are electrically coupled together (block 66). As assembled, the plurality of units cooperatively transfer heat via thermotunneling of electronics between the first and second thermally conductive substrates of each respective unit, thereby providing the desired cooling or heating of an object. In one embodiment, a metal layer may be disposed on the substrates to provide the electrical coupling while assembling the plurality of units. Examples of such metals include Nickel, Gold and Titanium.

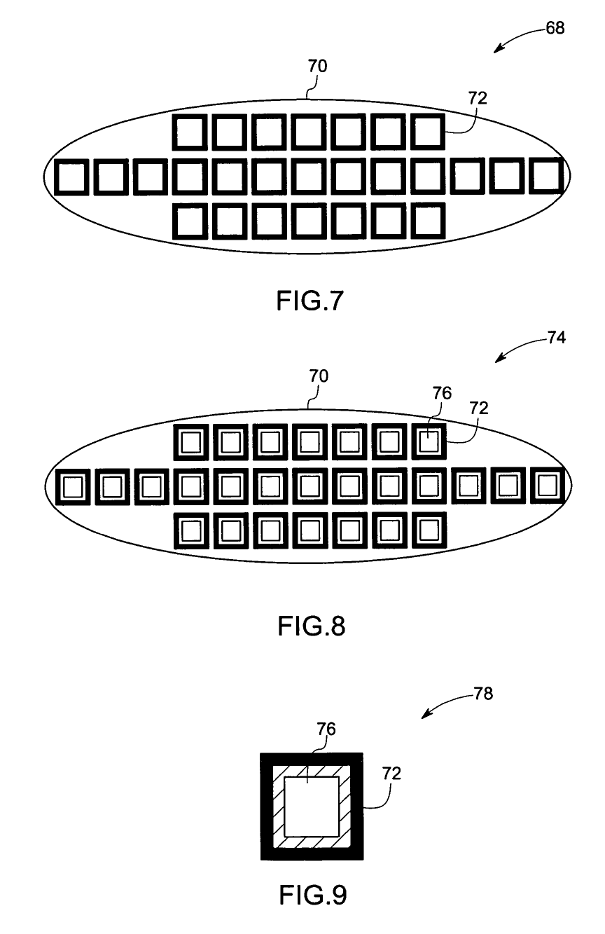

FIGS. 7 and 8 illustrate components of the thermotunneling-based heat transfer devices of FIGS. 1, 2, and 3 fabricated by the techniques described in FIGS. 4, 5, and 6 in accordance with certain embodiments of the present technique. Referring now to FIG. 7, this figure illustrates an insulatingly patterned configuration or patterned electrical barrier layer 68 on a thermally conductive substrate 70. In certain embodiments, the substrate 70 is a substantially atomically flat material, such as described in detail above. Further, the substrate 70 may comprise an electrically insulating substrate having an electrically conductive coating disposed on the electrically insulating substrate. The patterned electrical barrier layer 68 includes a plurality of insulative boundaries 72 disposed on the substrate 70. In the illustrated embodiment, the insulative boundaries 72 are rectangular frames, borders, or windows. However, other shapes and configurations of the insulative boundaries are within the scope of the present technique.

The insulative boundaries 72 comprise a material having a low thermal conductivity typically in the range of about 0.01 W/cm K to about 0.15 W/cm K. Examples of such materials include oxides, nitrides and silica-based aerogels. In one embodiment, the insulative boundaries 72 may be deposited on the substrate 70. In another embodiment, the insulative boundaries 72 may be grown on the substrate 70. Further, the patterning of the insulative boundaries 72 may be achieved by techniques such as etching, photoresist, shadow masking, lithography and so forth. It should be noted that embodiments of the heat transfer device manufactured by the exemplary techniques described above are passive devices that enable a heat transfer between two electrodes by maintaining a desired thermotunneling gap. Thus, certain embodiments of the heat transfer device do not use any active components or a feed back control circuitry for controlling the thermotunneling gap between the electrodes.

FIG. 8 illustrates an exemplary insulatively bounded low work function pattern 74 in accordance with embodiments of the present technique. As illustrated, each of the insulative boundaries 72 surrounds a low work function material 76 on the substrate 70. In other words, the patterned electrical barrier layer 68 is aligned with a similar pattern of low work function material 76, such that each portion of the low work function material 76 is bounded by the respective insulative boundary 72. As illustrated, each portion of the low work function material 76 has a rectangular shape adapted to the shape and confines of the respective insulative boundary 72. Accordingly, modification to the shapes of the insulative boundaries (72) will result in a variety of potential shapes of the portion of low work function materials 76. Thus, other shapes are within the scope of the present technique.

In certain embodiments, the low work function material 76 is disposed selectively on the substrate 70 by using techniques such as etching, photo resist, lithography, and so forth. Further, the low work function material 76 may be deposited on the substrate via techniques such as ion implantation, evaporation, sputtering, vapor deposition, plasma enhanced chemical vapor deposition (PECVD), chemical vapor deposition (CVD), pulsed laser ablation (PLA), or combinations thereof. In this embodiment, the low work function material 76 comprises an alkalide. In various embodiments, the low work function material 76 may comprise an electride, an oxide of barium, a rare-earth sulfide, strontium, calcium and their combinations thereof. In certain embodiments, the low work function material comprises a multilayer thin film structure. In this embodiment, the multilayer thin film structure comprises at least one metal layer disposed adjacent to at least one wide band-gap semiconductor layer. In addition, the low work function material may be deposited on the entire substrate either below or above the patterned electrical barrier.

As discussed above, another thermally conductive substrate (not shown) is bonded to the thermally conductive substrate 70 over the insulatively bounded low work function pattern 74, as illustrated in FIG. 8. The added substrate also includes a low work function material, such as a pattern aligned with the low work function material 76 of FIG. 8. In the bonded structure, the patterned electrical barrier layer 68 offsets these low work function materials from one another to form a thermotunneling gap, as discussed in further detail below. The bonded structure is then cut into separate units based on the patterned electrical barrier layer 68. For example, the bonded structure may be cut in the region surrounding each of the insulative boundaries 72. Referring now to FIG. 9, this figure illustrates a cross sectional view of an exemplary unit 78 extracted from a bonded structure having another thermally conductive substrate (not shown) bonded to the thermally conductive substrate 70 of FIG. 8 in accordance with embodiments of the present technique. As illustrated, the unit 78 comprises one of the insulative boundaries 72 of the patterned electrical barrier layer 68 disposed about a portion of the low work function material 76.

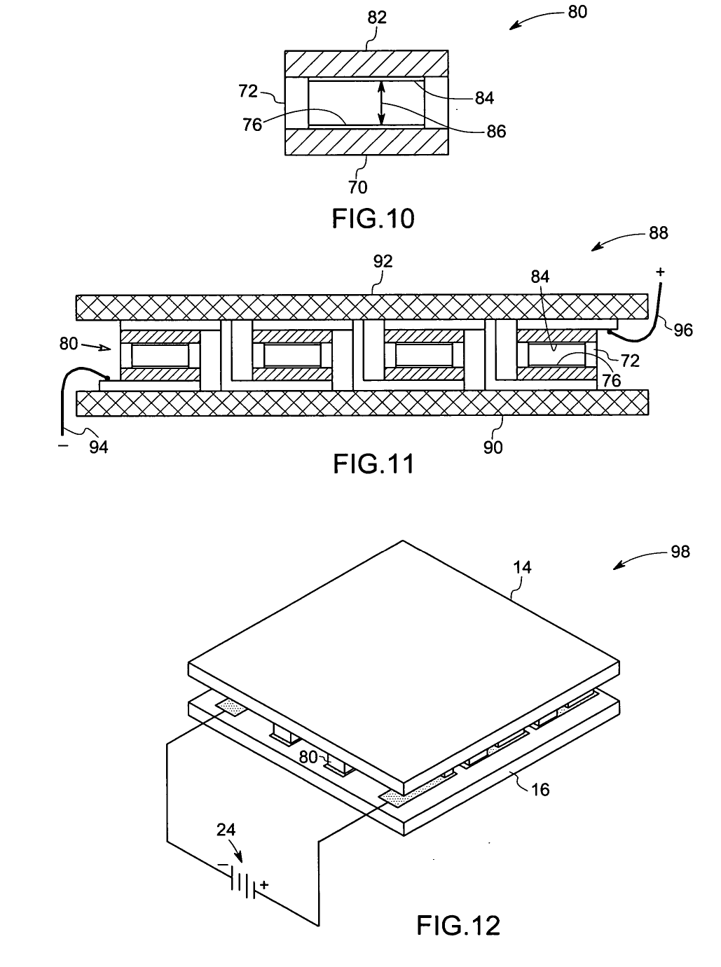

It should be noted that, a plurality of units 78 may be extracted from the foregoing bonded structure to form the thermotunneling devices of FIGS. 1, 2 and 3. FIG. 10 is a side view illustrating an exemplary embodiment of the bonded structure of FIG. 9 representing a heat transfer device, e.g., a thermotunneling device 80, which thermotunneling device 80 is applicable to a variety of heating and cooling systems. As illustrated, the thermotunneling device 80 includes the thermally conductive substrate 70 and an opposite thermally conductive substrate 82. The thermotunneling device 80 also includes one of the insulative boundaries 72 of the patterned electrical barrier 68 disposed about the low work function material 76. In addition to the low work function material 76 disposed on the lower substrate 70, the upper substrate 82 includes a low work function material 84 disposed opposite the low work function material 76. As discussed above, the insulative boundary 72 has a thickness that generally defines a thermotunneling gap 86 between the low work function materials 76 and 84 on the lower and upper thermally conductive substrates 70 and 82, respectively. As discussed in detail above, the thermotunneling device 80 may be manufactured using a variety of materials and manufacturing techniques.

FIG. 11 illustrates a cross-sectional side view of a heat transfer device or assembled module 88 having a plurality of thermotunneling devices 80 in accordance with embodiments of the present technique. In the illustrated embodiment, the thermotunneling devices 80 are mounted between opposite substrates 90 and 92 and are electrically coupled to form the assembled module 84. In this manner, the thermotunneling devices 80 cooperatively provide a desired heating or cooling capacity, which can be used to transfer heat from one object or area to another. In certain embodiments, the plurality of thermotunneling devices 80 may be coupled via a conductive adhesive, such as, silver filled epoxy or a solder alloy. The conductive adhesive or the solder alloy for coupling the plurality of thermotunneling devices 80 may be selected based upon a desired processing technique and a desired operating temperature of the heat transfer device. Finally, the assembled module 88 is coupled to an input voltage source via leads 94 and 96. In operation, the input voltage source provides a flow of current through the thermotunneling devices 80, thereby creating a tunneling flow of electrons between the substrates 90 and 92. As a result of this tunneling flow of electrons, the thermotunneling devices 80 facilitate heat transfer between the substrates 90 and 92.

FIG. 12 illustrates a perspective view of a heat transfer module 98 having an array of thermotunneling devices 80 in accordance with embodiments of the present technique. In this embodiment, the thermotunneling devices 80 are employed in a two-dimension array to meet a thermal management need of an environment or application. The thermotunneling devices 80 may be assembled into the heat transfer module 98 where the devices 80 are coupled electrically in series and thermally in parallel to enable the flow of electrons from first object 14 in the module 98 to the second object 16 in the module 98, thus transferring the heat from the first object 14 to the second object 16.

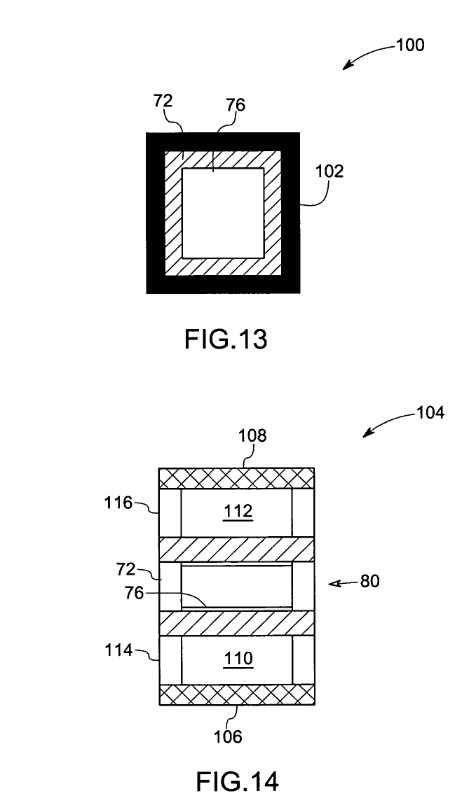

FIG. 13 illustrates a cross-sectional view of another exemplary thermotunneling-based heat transfer device 100 having the insulative boundary 72 disposed about a portion of the low work function material 76 illustrated FIG. 8 in accordance with embodiments of the present technique. In this embodiment, the heat transfer device 100 comprises an insulating material 102 disposed on edges of the heat transfer device 100 for enhancing hermiticity of the heat transfer device 96. Examples of such insulating materials 102 include nitrides, diamond like carbon coating and frit glasses. The insulating material 102 may be applied on the edges of the heat transfer device 100 by techniques such as thermal deposition, sputtering, plasma assisted deposition, physical placement of a perform and subsequent reflow in the case of a glass perform.

FIG. 14 illustrates a cross-sectional side view of another alternative thermotunneling-based heat transfer device 104 in accordance with embodiments of the present technique. In the presently contemplated configuration, thermally conductive substrates 106 and 108 having cavities 110 and 112 are bonded to the thermotunneling device 80. Moreover, the cavities 110 and 112 of the thermally conductive substrates 106 and 108 are aligned with the low work function material 76 of the thermotunneling device 80. Further, spacers 114 and 116 are employed for coupling the thermally conductive substrates 106 and 108 with the thermotunneling device 80. In this embodiment, the additional thermally conductive substrates 106 and 108 enhance the reliability of the thermotunneling device 80 and are particularly advantageous for heating or cooling of large objects. However, other embodiments may include more thermally conductive substrates and outer cavities to the heat transfer device 80 for use in meeting thermal management needs of an environment.

The various aspects of the technique described hereinabove find utility in a variety of heating/cooling systems, such as refrigeration, air conditioning, electronics cooling, industrial temperature control, power generation, and so forth. These include air conditioners, water coolers, refrigerators, heat sinks, climate control seats and so forth. The heat transfer device as described above may be employed in refrigeration systems such as for household refrigeration and industrial refrigeration. In addition, such heat transfer devices may be employed for cryogenic refrigeration, such as for liquefied natural gas (LNG) or superconducting devices. Further, the heat transfer device may be employed in systems for ventilation and air conditioning. Examples of such systems include air conditioners and dehumidifiers. In addition, the heat transfer device may be employed for power generation/waste heat recovery in different applications by maintaining a thermal gradient between two electrodes. Examples of such applications include gas turbine exhausts, furnace exhausts, exhausts of vehicles and so forth.

The passive heat transfer device described herein above may also be employed for thermal energy conversion and for thermal management. It should be noted that the materials and the manufacturing techniques for the heat transfer device may be selected based upon a desired thermal management need of an object. Such devices may be used for cooling of microelectronic systems such as microprocessor and integrated circuits. Further the heat transfer devices may also be employed for thermal management of semiconductors, photonic devices and infrared sensors. As noted above, the method described here may be advantageous in relatively precise control of the spacing and alignment between adjacent electrodes of a heat transfer device to meet the desired thermal management needs in the environments mentioned above.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method of manufacturing a heat transfer device, comprising:
providing first and second thermally conductive substrates that are substantially atomically flat;
providing a patterned electrical barrier on the first or second thermally conductive substrates;
disposing a low work function material on the first or second thermally conductive substrates in at least an area oriented between the patterned electrical barrier in a configuration in which the first and second thermally conductive substrates are positioned opposite from one another;
bonding the first and second thermally conductive substrates in the configuration; and
extracting a plurality of units having opposite sections of the first and second thermally conductive substrates, each unit having a portion of the patterned electrical barrier disposed about the low work function material.

2. The method of claim 1, wherein providing first and second thermally conductive substrates comprises providing electrically conducting substrates.

3. The method of claim 1, wherein providing first and second thermally conductive substrates comprises providing an electrically insulating substrate having an electrically conductive coating disposed on the electrically insulating substrate.

4. The method of claim 1, further comprising providing the patterned electrical barrier on each of the first and second thermally conductive substrates.

5. The method of claim 1, further comprising disposing the low work function material on each of the first and second thermally conductive substrates in at least the area oriented between the patterned electrical barrier in the configuration in which the first and second thermally conductive substrates are positioned opposite from one another.

6. The method of claim 1, wherein providing the patterned electrical barrier comprises growing an electrical barrier layer on the first or second thermally conductive substrates.

7. The method of claim 1, wherein providing the patterned electrical barrier comprises depositing an electrical barrier layer on the first or second thermally conductive substrates.

8. The method of claim 1, wherein the patterned electrical barrier has a thickness of about 4 nanometers to about 20 nanometers.

9. The method of claim 1, wherein providing the patterned electrical barrier comprises creating an electrical barrier layer and etching the electrical barrier layer to form the patterned electrical barrier.

10. The method of claim 1, wherein providing the patterned electrical barrier layer comprises creating the patterned electrical barrier via photoresist, shadow masking or lithography.

11. The method of claim 1, wherein disposing the low work function material comprises depositing a low work function material on the first or second thermally conductive substrates by ion implantation, evaporation, sputtering, vapor deposition, plasma enhanced chemical vapor deposition (PECVD), chemical vapor deposition (CVD), pulsed laser deposition (PLD), laser ablation, or different combinations thereof.

12. The method of claim 1, comprising bonding at least one thermally conductive substrate having a cavity to each of the first and second thermally conductive substrates, wherein the cavity is aligned with the low work function material and wherein the bonding is performed in vacuum to form a vacuum within the cavity.

13. The method of claim 1, comprising bonding at least one thermally conductive substrate having a cavity to each of the first and second thermally conductive substrates, wherein the cavity is aligned with the low work function material and wherein the bonding is performed in an inert gas environment to fill the cavity with a desired gas.

14. The method of claim 1, comprising coating edges of each of the plurality of units to improve hermeticity of the plurality of units.

15. The method of claim 1, comprising electrically coupling the plurality of units to one another.

16. A method of manufacturing a heat transfer device, comprising:
providing first and second thermally conductive substrates that are substantially atomically flat, one of the first or second thermally conductive substrates having a patterned electrical barrier surrounding a low work function material in at least an area oriented between the patterned electrical barrier in a configuration in which the first and second thermally conductive substrates are positioned opposite from one another;
bonding the first and second thermally conductive substrates in the configuration; and
extracting a unit having opposite sections of the first and second thermally conductive substrates, the unit having a portion of the patterned electrical barrier disposed about the low work function material, the portion defining a thermotunneling gap between the first and second thermally conductive substrates.

17. The method of claim 16, wherein providing first and second thermally conductive substrates comprises providing electrically conducting substrates.

18. The method of claim 16, wherein providing first and second thermally conductive substrates comprises providing an electrically insulating substrate having an electrically conductive coating disposed on the electrically insulating substrate.

19. The method of claim 16, wherein the patterned electrical barrier has a thickness of about 4 nanometers to about 20 nanometers.

20. The method of claim 16, comprising bonding at least one thermally conductive substrate having a cavity to each of the first and second thermally conductive substrates, wherein the cavity is aligned with the low work function material and wherein the bonding is performed in vacuum to form a vacuum in the cavity.

21. The method of claim 16, comprising bonding at least one thermally conductive substrate having a cavity to each of the first and second thermally conductive substrates, wherein the cavity is aligned with the low work function material and wherein the bonding is performed in an inert gas environment to fill the cavity with a desired gas.

22. The method of claim 16, comprising coating edges of each of the plurality of units to improve hermeticity of the plurality of units.

23. The method of claim 16, comprising electrically coupling the plurality of units to one another.

24. A method of manufacturing a heat transfer device, comprising:
providing a plurality of units having opposite thermally conductive substrates, each having a patterned electrical barrier disposed about a low work function material to form a thermotunneling gap;
mounting the plurality of units between opposite substrates; and
electrically coupling the plurality of units.

25. The method of claim 24, comprising coating edges of each of the plurality of units to improve hermeticity of the plurality of units.

26. The method of claim 24, wherein electrically coupling the plurality of units comprises coupling the plurality of units by a conductive adhesive.

27. The method of claim 24, wherein electrically coupling the plurality of units comprises coupling the plurality of units by a solder alloy.

28. A heat transfer device, comprising:
first and second thermally conductive substrates that are positioned opposite from one another, wherein the first and second thermally conductive substrates are each substantially atomically flat;
a patterned electrical barrier disposed between the first and second thermally conductive substrates on the first or second thermally conductive substrates; and
a low work function material disposed between the first and second thermally conductive substrates on the first or second thermally conductive substrates in at least an area oriented between the patterned electrical barrier, wherein introduction of a current flow between the first and second thermally conductive substrates enables heat transfer between the first and second thermally conductive substrates via a flow of electrons between the first and second thermally conductive substrates.

29. The device of claim 28, wherein the heat transfer device comprises a passive device configured to transfer heat between the first and second thermally conductive substrates across a thermotunneling gap.

30. The device of claim 28, wherein the first and second thermally conductive substrates comprise electrically conducting substrates.

31. The device of claim 28, wherein the first and second thermally conductive substrates comprise an electrically insulating substrate having an electrically conductive coating disposed on the electrically insulating substrate.

32. The device of claim 28, wherein the patterned electrical barrier is disposed between the first and second thermally conductive substrates on each of the first and second thermally conductive substrates.

33. The device of claim 28, wherein the low work function material is disposed between the first and second thermally conductive substrates on each of the first and second thermally conductive substrates in the area oriented between the patterned electrical barrier.

34. The device of claim 28, wherein the first or second thermally conductive substrates comprise doped n-type silicon wafer.

35. The device of claim 28, wherein the first or second thermally conductive substrates comprise doped p-type silicon wafer.

36. The device of claim 28, wherein the first or second thermally conductive substrates comprise a thermally and electrically conductive metal.

37. The device of claim 28, wherein the patterned electrical barrier comprises an oxide.

38. The device of claim 28, wherein the patterned electrical barrier comprises a nitride.

39. The device of claim 28, wherein the patterned electrical barrier comprises a silica-based aerogel.

40. The device of claim 28, wherein the patterned electrical barrier layer comprises a polymer.

41. The device of claim 28, wherein the electrical barrier layer has a thickness of about 4 nanometers to about 20 nanometers.

42. The device of claim 28, comprising at least one thermally conductive substrate having a cavity coupled to each of the first and second thermally conductive substrates, wherein the cavity is aligned with the low work function material.

43. The device of claim 28, wherein the low work function material comprises an alkalide.

44. The device of claim 28, wherein the low work function material comprises an electride.

45. The device of claim 28, wherein the low work function material comprises an oxide of barium.

46. The device of claim 28, wherein the low work function material comprises strontium.

47. The device of claim 28, wherein the low work function material comprises calcium.

48. The device of claim 28, wherein the low work function material comprises a multilayer structure, wherein the multilayer structure comprises a plurality of thin films of metal and a plurality of wide-band-gap semiconductors.

49. The device of claim 28, comprising a plurality of units having opposite sections of the first and second thermally substrates, each unit having a portion of the patterned electrical barrier disposed about the low work function material.

50. The device of claim 49, comprising a coating disposed on the edges of each of the plurality of units to improve hermeticity of the plurality of units.

51. The device of claim 28, wherein the heat transfer device is adapted to generate power by maintaining a temperature gradient between the first and second thermally conductive substrates.

52. The device of claim 28, wherein the heat transfer device is configured for use in a refrigeration system.

53. The device of claim 28, wherein the heat transfer device is configured for use in one of a cooling system or an air conditioning system.

54. The device of claim 28, wherein the heat transfer device is configured for thermal energy conversion.

55. The device of claim 28, wherein the heat transfer device is configured for cooling a microelectronic system.

56. A heat transfer system, comprising:
a first object;
a second object; and
a heat transfer device adapted to transfer heat between the first and second objects, the heat transfer device comprising:
first and second thermally conductive substrates that are substantially atomically flat;
a patterned electrical barrier disposed on the first or second thermally conductive substrates; and
a low work function material disposed on the first or second thermally conductive substrates in at least an area oriented between the patterned electrical barrier in a configuration in which the first and second thermally conductive substrates are positioned opposite from one another, wherein introduction of a current flow between the first and second thermally conductive substrates enables heat transfer between the first and second thermally conductive substrates via a flow of electrons between the first and second thermally conductive substrates.

57. The system of claim 56, wherein the first and second thermally conductive substrates comprise an electrically conducting substrate.

58. The system of claim 56, wherein the first and second thermally conductive substrates comprise an electrically insulating substrate having an electrically conductive coating disposed on the electrically insulating substrate.

59. The system of claim 56, wherein the patterned electrical barrier is disposed on each of the first and second thermally conductive substrates.

60. The system of claim 56, wherein the low work function material is disposed on each of the first and second thermally conductive substrates in the area oriented between the patterned electrical barrier in the configuration in which the first and second thermally conductive substrates are positioned opposite from one another.

61. The system of claim 56, wherein the heat transfer device is adapted to provide cooling of the first or second objects.

62. The system of claim 56, wherein the heat transfer device is adapted to generate power by maintaining a temperature gradient between the first and second objects.

63. The system of claim 56, wherein the heat transfer device is configured for use in a refrigeration system.

64. The system of claim 56, wherein the heat transfer device is configured for use in one of a cooling system or an air conditioning system.

65. The system of claim 56, wherein the heat transfer device is configured for thermal energy conversion.

66. The system of claim 56, wherein the heat transfer device is configured for cooling a microelectronic system.

67. A method of operation of a heat transfer device comprising:
passing hot electrons across a thermotunneling gap between first and second thermally conductive substrates, wherein the thermotunneling gap is formed by a patterned electrical barrier disposed about a low work function material on one of the first or second thermally conductive substrates.

68. The method of claim 67, wherein passing hot electrons comprises cooling a first member in thermal communication with the first thermally conductive substrate.

69. The method of claim 67, wherein passing hot electrons comprises cooling a closed environment.

70. The method of claim 67, wherein passing hot electrons comprises heating a second member in thermal communication with the second thermally conductive substrate.

71. The method of claim 67, wherein passing hot electrons comprises heating a closed environment.

72. The method of claim 67, comprising transferring heat between first and second thermally conductive substrates by a plurality of units having opposite sections of the first and second thermally conductive substrates, each unit having a portion of the patterned electrical barrier disposed about a low work function material
